(19) United States
(12) Patent Application Publication
(10) Pub. No.: US 2025/0301834 A1
(43) Pub. Date: Sep. 25, 2025

(54) SEMICONDUCTOR LIGHT EMITTING APPARATUS

(71) Applicant: STANLEY ELECTRIC CO., LTD., Tokyo (JP)

(72) Inventors: Daisuke WATANABE, Tokyo (JP); Yusuke YAMASHITA, Tokyo (JP); Yuichi ITO, Tokyo (JP); Kodai SHIINA, Tokyo (JP); Yoshihiro KOBAYASHI, Tokyo (JP)

(73) Assignee: STANLEY ELECTRIC CO., LTD., Tokyo (JP)

(21) Appl. No.: 19/087,952

(22) Filed: Mar. 24, 2025

(30) Foreign Application Priority Data
Mar. 25, 2024 (JP) 2024-047862

(51) Int. Cl. H10H 20/857; H10H 20/01; H10H 20/854

(52) U.S. Cl. CPC H10H 20/857; H10H 20/0362; H10H 20/0364; H10H 20/854

(57) ABSTRACT

Provided are a semiconductor light emitting apparatus and a method for manufacturing the semiconductor light emitting apparatus, which result in high adhesion between a lead frame and sealing resin and high reliability. A resin frame is disposed on a first lead electrode and a second lead electrode disposed on an identical plane with a gap therebetween, thereby forming a housing. The upper surfaces of the first lead electrode and the second lead electrode form the bottom surface of a recess surrounded by the frame. A light emitting device is bonded onto the second lead electrode in the recess. A first sealing member contacts the bottom surface of the recess around the light emitting device and an inner wall surface of the frame. A second sealing member covers the light emitting device and the first sealing member, and fills the recess. Resin forming the frame extends into the gap between the first lead electrode and the second lead electrode to fill the gap. The upper surface of the resin filling the gap is covered with the first sealing member.

### CROSS-REFERENCE TO RELATED APPLICATIONS

This application claims the benefit of and priority to Japanese Patent Application No. 2024-47862 filed on Mar. 25, 2024, and the content thereof is incorporated herein by reference in its entirety.

### BACKGROUND OF THE INVENTION

### 1. Field of the Invention

The present invention relates to a semiconductor light emitting apparatus having a structure in which a semiconductor light emitting device is fixed onto a lead frame with an adhesive member and the periphery thereof is sealed with resin.

### 2. Description of Related Art

From Patent Literatures 1 and 2, a semiconductor light emitting apparatus has been known, which has a structure in which a semiconductor light emitting device and a resin frame surrounding such a semiconductor light emitting device are mounted on a lead frame and a space including the semiconductor light emitting device and surrounded by the frame is sealed with sealing resin. The semiconductor light emitting apparatus having this structure has a problem that the lead frame is easily separated from the frame and the sealing resin.

For this reason, Patent Literature 1 discloses that recesses are provided in the periphery of a region where the semiconductor light emitting device is mounted on the lead frame and the inner periphery of the frame and are filled with resin to improve adhesion of the lead frame to the frame and the sealing resin.

Patent Literature 2 discloses a structure in which a frame is molded by transfer molding with thermosetting resin and a lead frame is provided with a cutout to improve adhesion between the thermosetting resin and the lead frame.

### CITATION LIST

### Patent Literature

PTL 1: JP2012-182215A

PTL 2: JP2010-62272A

### SUMMARY OF THE INVENTION

In the techniques of Patent Literatures 1 and 2, the lead frame and the frame are in close contact with each other at the time when the resin frame is formed on the lead frame. However, when physical stress due to bonding of the light emitting device to the lead frame, wire bonding, or the like is applied to the lead frame, the lead frame and the resin frame may be separated from each other. When the lead frame and the resin frame are separated from each other, corrosive gas, such as nitrogen oxide or sulfur oxide, contained in atmospheric air may reach the light emitting device or a bonding wire in the light emitting apparatus through a gap between the lead frame and the frame, which leads to corrosion of these light emitting device and bonding wire.

An object of the present invention is to provide a semiconductor light emitting apparatus and a method for manufacturing the semiconductor light emitting apparatus, which result in high adhesion between a lead frame and sealing resin and high reliability.

In order to accomplish the above-described object, the semiconductor light emitting apparatus of the present invention includes a housing, a light emitting device, a first sealing member, and a second sealing member. The housing includes a first lead electrode and a second lead electrode disposed on an identical plane with a gap therebetween, and a resin frame disposed on the first lead electrode and the second lead electrode. The frame forms a recess surrounded by the frame, and the upper surfaces of the first lead electrode and the second lead electrode form the bottom surface of the recess. The light emitting device is bonded onto the second lead electrode via an adhesive member in the recess. The first sealing member contacts the bottom surface of the recess around the light emitting device and an inner wall surface of the frame. The second sealing member covers the light emitting device and the first sealing member, and fills the recess. Resin forming the frame extends into the gap between the first lead electrode and the second lead electrode to fill the gap. The upper surface of the resin filling the recess forms part of the bottom surface of the recess. The upper surface of the resin filling the gap is covered with the first sealing member.

According to the present invention, the semiconductor light emitting apparatus and the method for manufacturing the semiconductor light emitting apparatus can be provided, which result in high adhesion between the lead frame and the sealing resin and high reliability.

### BRIEF DESCRIPTION OF THE DRAWINGS

FIGS. 1A to 1C are a top view, a long side view, and a short side view of a semiconductor light emitting apparatus 1 of an embodiment of the present invention, FIGS. 1D and 1E are a sectional view taken along A-A line and a sectional view taken along B-B line, FIG. 1F is a top view showing a state where sealing resin is removed, and FIG. 1G is an enlarged sectional view taken along B-B line;

FIGS. 2A to 2D are a top view, a longitudinal side view, and a short side view of lead electrodes 10, 20 and a frame 40 and a sectional view thereof taken along A-A line;

FIG. 3 is a flowchart showing steps of manufacturing the semiconductor light emitting apparatus 1 of the embodiment;

FIGS. 4A to 4C are views for describing the steps of manufacturing the semiconductor light emitting apparatus 1 of the embodiment;

FIGS. 5A to 5C are views for describing the steps of manufacturing the semiconductor light emitting apparatus 1 of the embodiment;

FIGS. 6A to 6C are views for describing the steps of manufacturing the semiconductor light emitting apparatus 1 of the embodiment; and

FIG. 7 is a sectional view of a semiconductor light emitting apparatus 1 of a modification of the embodiment.

### DESCRIPTION OF EMBODIMENTS

An embodiment of the present invention will be described by way of example.

### Embodiment

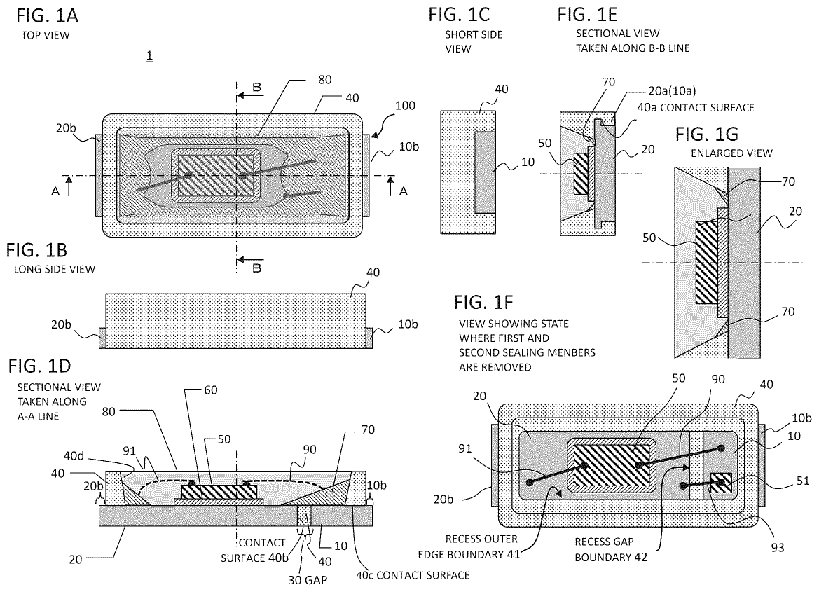

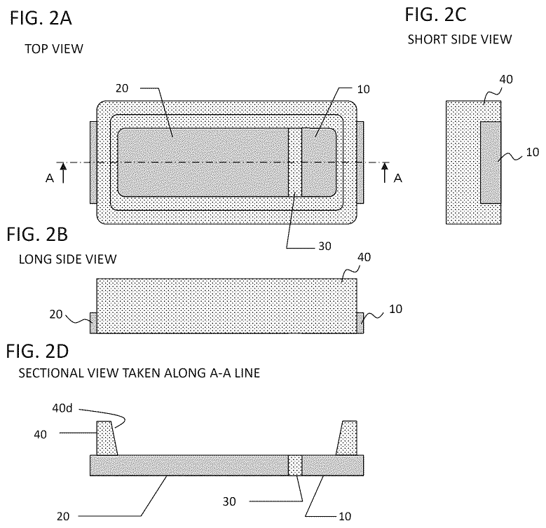

First, the structure of a semiconductor light emitting apparatus 1 will be described with reference to FIGS. 1A to 2D. FIGS. 1A to 1C are a top view, a longitudinal side view, and a short side view of the semiconductor light emitting apparatus 1, FIGS. 1D and 1E are a sectional view taken along A-A line and a sectional view taken along B-B line, FIG. 1F is a top view showing a state where sealing resin is removed, and FIG. 1G is an enlarged sectional view taken along B-B line. Note that hereinafter, a surface facing up in FIGS. 1B and 1D will be described as an upper surface and a surface facing down will be described as a lower surface.

The semiconductor light emitting apparatus 1 of the embodiment includes a housing 100, a light emitting device 50, a first sealing member 70, and a second sealing member 80. The housing 100 includes a first lead electrode 10 and a second lead electrode 20 disposed on the same plane with a gap therebetween, and a resin frame 40 disposed on the first lead electrode 10 and the second lead electrode 20 and at the peripheral edges thereof. The housing 100 has a bathtub-shaped recess. The first lead electrode 10 and the second lead electrode 20 have upper surfaces exposed on the bottom surface of the recess of the housing 100. A protective device 51 and the light emitting device 50 are mounted on the upper surfaces of the first lead electrode 10 and the second lead electrode 20. The first sealing member 70 is disposed so as to cover the protective device 51 and surround the light emitting device 50. That is, the first sealing member 70 is apart from the light emitting device 50. The second sealing member 80 covers the light emitting device 50 and the first sealing member 70, and fills the recess.

Hereinafter, in a case where the first lead electrode 10 and the second lead electrode 20 are not distinguished from each other, these electrodes will be described as lead electrodes 10, 20. Moreover, in a case where the first sealing member 70 and the second sealing member 80 are not distinguished from each other, these members will be described as sealing members 70, 80.

### (Housing)

The housing 100 will be described with reference to FIGS. 1A to 1F and FIGS. 2A to 2D. FIG. 1A is the top view, FIG. 1B is the longitudinal side view, FIG. 1C is the short side view, FIG. 1D is the sectional view taken along A-A line, and FIG. 1E is the sectional view taken along B-B line.

As shown in FIG. 2A, the housing 100 has a quadrangular shape (rectangular shape) with the right-left direction (A-A direction) in the figure as a longitudinal side and the up-down direction (direction perpendicular to the A-A direction) as a short side. Specifically, the flat plate-shaped first lead electrode 10 and second lead electrode 20 in the substantially rectangular shape are arranged apart from each other in the longitudinal direction with a gap 30 therebetween in top view. The frame 40 is made of resin, is mounted along the peripheral edges of the lead electrodes 10, 20, and forms the quadrangular (rectangular) recess surrounded by the frame 40. In addition, the frame 40 surrounds the side surfaces of the lead electrodes 10, 20 at the peripheral edges thereof. The resin forming the frame 40 extends to the gap 30 between the first lead electrode 10 and the second lead electrode 20, and fills the gap 30 (in the present embodiment, the resin extending into the gap 30 will be also referred to as the frame 40). The resin frame 40 is formed by insert molding. That is, the lead electrodes 10, 20 and the frame 40 are a composite molded article (insert molded article), and forms the housing 100. The bottom surface of the recess of the housing 100 is a quadrangular (rectangular) flat surface on which part of the upper surfaces of the lead electrodes 10, 20 is exposed. As shown in FIG. 2D, an inner wall surface 40d of the frame 40 is inclined such that a space in the recess expands as extending upward. The upper end surface of the frame 40 is at a position higher than the upper surface of the light emitting device 50.

The side surfaces of the lead electrodes 10, 20 in the longitudinal direction of the housing 100 are covered with the frame 40. Moreover, protrusions 10b, 20b which are end portions of the lead electrodes 10, 20 protrude outward from the short sides of the frame 40. The side surfaces of the lead electrodes 10, 20 in the longitudinal direction of the housing 100 are provided with steps 10a, 20a. The frame 40 extends on the steps 10a, 20a such that the lead electrodes 10, 20 are embedded therein. Thus, a contact surface 40a of the frame 40 closely contacting the lead electrodes 10, 20 includes multiple surfaces, which improves adhesion between the lead electrodes 10, 20 and the frame 40.

The first lead electrode 10 and the second lead electrode 20 contain copper (Cu) as a base material, and electrode coatings of nickel (Ni) and gold (Au) are stacked in this order on the surfaces of these electrodes (the multilayer electrode coating will be hereinafter indicated by Ni/Au). The coefficient of thermal expansion of Cu as the base material is 17.8 ppm° C.⁻¹, and the hardness thereof is 120 HV (equal to or greater than the maximum value of a shore D range described later). Examples of the base material to be used may include aluminum (Al) or iron (Fe)-nickel (Ni)-cobalt (Co) alloy and the like. Moreover, examples of the electrode coating to be used may include titanium (Ti)/Au, Ni/silver (Ag), Ti/Ag, and the like.

The frame 40 is made of light-reflecting resin obtained by mixing dimethyl silicone resin as medium resin with 10 wt % to 35 wt % of titanium oxide (TiO₂) particles, which have a particle size of 200 nm to 300 nm, as light-reflecting particles. The coefficient of thermal expansion of the dimethyl silicone-based resin used in the embodiment is 212 ppm° C.⁻¹, and the hardness (durometer type A (shore A) according to JIS K 6253) thereof is A65 to A78. Note that examples of the medium resin to be used may include dialkyl silicone-based resins, epoxy-based resins, acrylic-based resins, polycarbonate-based resins, and the like. Moreover, examples of the light-reflecting particle to be used may include particles of alumina (Al₂O₃), zirconia (ZrO₂), highly-refractive glass, and the like.

### (Light Emitting Device)

The light emitting device 50 is a semiconductor light emitting device (LED) having a rectangular shape in top view and including a light emitting semiconductor layer configured such that an n-type semiconductor layer, a light emitting layer, and a p-type semiconductor layer are stacked in this order and a device substrate supporting the light emitting semiconductor layer on one surface (lower surface) thereof. Further, the light emitting device 50 includes, on the other surface (upper surface) of the light emitting semiconductor layer, a pair of device electrodes each connected to the n-type semiconductor layer and the p-type semiconductor layer. The light emitting semiconductor layer is a gallium nitride-based (GaN-based) semiconductor crystal layer that emits blue light (for example, having a wavelength of 440 nm to 460 nm). The device substrate is an insulating sapphire crystal allowing light emitted from the light emitting semiconductor layer to penetrate therethrough.

The light emitting device 50 has a lower surface (lower surface of the device substrate) bonded (die-bonded) to the upper surface of the second lead electrode 20 via an adhesive member 60. Moreover, the pair of device electrodes of the light emitting device 50 are connected to the first lead electrode 10 and the second lead electrode 20 via an Au bonding wire 90 and an Au bonding wire 91. Thus, voltage is applied to the lead electrodes 10, 20, and accordingly, the light emitting device 50 emits light from the upper and side surfaces thereof.

The adhesive member 60 is larger than the lower surface of the light emitting device 50, and is provided such that the side surfaces of the light emitting device 50 are exposed. The adhesive member 60 is made of, for example, light-reflecting resin obtained by mixing silsesquioxane-based (SQ-based) resin as medium resin with titanium oxide particles having a particle size of 1 nm to 500 nm as light-reflecting particles. Thus, light penetrating the light emitting device 50 toward the lower surface thereof is reflected toward the upper surface by the adhesive member 60. Moreover, light penetrating the light emitting device 50 toward the side surfaces thereof is emitted from the side surfaces of the light emitting device 50 without being blocked by the adhesive member 60.

### (Protective Device)

The protective device 51 is a protective device that protects the light emitting device 50 from electrostatic breakdown or the like. The protective device 51 has a lower surface (lower electrode) bonded to the upper surface of the first lead electrode 10 via conductive resin. Moreover, an upper electrode of the protective device 51 is connected to the second lead electrode 20 via an Au bonding wire 93. That is, the protective device 51 of the embodiment is a vertical conduction type Zener diode (ZD). Note that examples of the protective device 51 to be used may include a capacitor, a varistor, and the like.

### (Sealing Member)

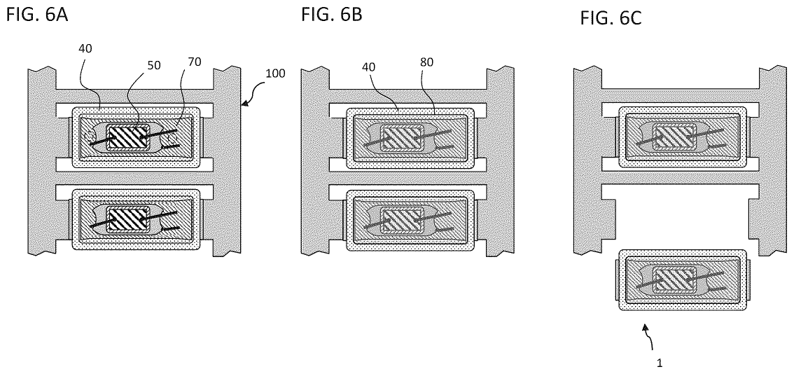

As shown in FIG. 1A and 6C, the first sealing member 70 is provided so as to cover a recess outer edge boundary 41 and a recess gap boundary 42. A recess outer edge boundary 41 is a boundary (corner) between the upper surfaces of the lead electrodes 10, 20 exposed on the bottom surface of the recess of the housing 100 and the inner wall surface 40d of the frame 40. A recess gap boundary 42 is a boundary between the gap 30 between the lead electrodes 10, 20 and the frame 40 filling the gap 30. That is, the first sealing member 70 is a sealing member that seals a boundary between the lead electrodes 10, 20 and the frame 40 in the recess of the housing 100. Thus, if the lead electrodes 10, 20 and the frame 40 are separated from each other, the first sealing member 70 can seal such a separated portion.

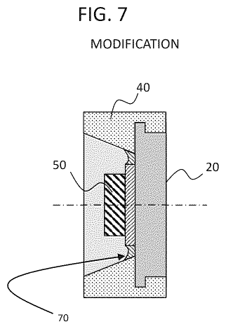

For example, the first sealing member 70 on the long side portion where the inner wall surface 40d of the frame 40 and the light emitting device 50 are close to each other, is provided from the upper surface of the second lead electrode 20 to the inner wall surface 40d of the frame 40. The first sealing member 70 does not reach the outer edge of the adhesive member 60 (see FIG. 1E). That is, the bottom surface of the recess between the frame 40 located on the short side of the bottom surface of the recess and the outer peripheral side of the light emitting device 50 facing the short side of a frame 40 is covered with the first sealing member 70 in the area closer to the frame body 40, while the area closer to the light-emitting element 50 is not covered with the first sealing member 70. Note that the first sealing member 70 may contact the outer edge of the adhesive member 60 (see FIG. 7). The thickness of the first sealing member 70 is set so as to increase toward the frame 40 (see FIG. 1D). That is, the first sealing member 70 covers (seals) the recess outer edge boundary 41 and the recess gap boundary 42. Moreover, the first sealing member 70 is disposed in a circular ring shape along the boundary between the lead electrodes 10, 20 and the inner wall surface 40d of the frame 40 around the light emitting device 50, and bonds and seals the boundary between the lead electrodes 10, 20 and the inner wall surface 40d of the frame 40. Thus, the first sealing member 70 can ease residual stress and external stress between the lead electrodes 10, 20 and the frame 40 in the housing 100, and can prevent separation of the contact surface 40a. In other words, adhesion between the lead electrodes 10, 20 and the frame 40 can be improved.

Particularly, contact surfaces 40c between the lead electrodes 10, 20 and the frame 40 at the base of the protrusions 10b, 20b protruding outward from the frame 40 is made of a single flat surface. And the surfaces of the lead electrodes 10, 20 facing each other across the gap 30 and the contact face 40b between the frame 40 are flat surface. The recess outer edge boundary 41 and the recess gap boundary 42 at these portions, are covered with the first sealing member 70 having a triangular sectional shape (see FIG. 1D), so that the residual stress and the external stress between the lead electrodes 10, 20 and the frame 40 can be eased and separation of the contact surfaces 40b, 40c can be prevented.

The first sealing member 70 is made of resin obtained by mixing silsesquioxane-based (SQ-based) resin as medium resin with titanium oxide particles, which are higher in hardness than the SQ-based resin and have a particle size of 1 nm to 500 nm, as aggregate particles (or light-reflecting particles). The SQ-based resin is resin expressed by a composition formula [(RSiO_{1.5})n] (R: alkyl group, n: integer) and having an intermediate hardness between inorganic silica [SiO₂] and organic silicone [(R2SiO)n]. The coefficient of thermal expansion of the SQ-based resin used in the embodiment is 188 ppm° C.⁻¹, and the hardness (durometer type D (shore D) according to JIS K 6253) thereof is D75. Moreover, the coefficient of thermal expansion of the titanium oxide particle is 7 ppm° C.⁻¹ to 9 ppm° C.⁻¹, and the hardness thereof is 950 HV. The same silsesquioxane-based (SQ-based) resin is used for the medium resin of the first sealing member 70 and the medium resin of the adhesive member 60, which leads to an advantage that the types of resin to be used can be reduced.

The hardness (D75) of the SQ-based resin which is the medium resin of the first sealing member 70 is an intermediate hardness between the hardness (120 HV) of Cu which is the base material of the lead electrodes 10, 20 and the hardness (A65 to A78) of the dimethyl silicone resin of the frame 40. That is, the hardness of the medium resin of the first sealing member 70 is greater than the hardness of the resin of the frame 40 and less than the hardness of the lead electrodes 10, 20. Thus, the residual stress and the external stress between the lead electrodes 10, 20 and the frame 40 can be eased and separation of the contact surfaces 40a, 40b, 40c can be prevented. In other words, adhesion between the lead electrodes 10, 20 and the frame 40 can be improved.

The coefficient of thermal expansion (188 ppm° C.⁻¹) of the SQ-based resin which is the medium resin of the first sealing member 70 is an intermediate coefficient of thermal expansion between the coefficient of thermal expansion (17.8 ppm° C.⁻¹) of Cu which is the base material of the lead electrodes 10, 20 and the coefficient of thermal expansion (212 ppm° C.⁻¹) of the dimethyl silicone resin of the frame 40, so that stress due to thermal fluctuation caused by power distribution to the semiconductor light emitting apparatus 1, an environmental temperature, or the like can be eased and separation of the contact surfaces 40a, 40b, 40c can be prevented. In other words, adhesion between the lead electrodes 10, 20 and the frame 40 can be improved.

Examples of the medium resin to be used for the first sealing member 70 may include epoxy-based resins, acrylic-based resins, polycarbonate-based resins, and the like having hardnesses or/and coefficients of thermal expansion similar to those of the silsesquioxane-based (SQ-based) resin.

Examples of the aggregate particle (or the light-reflecting particle) to be used for the first sealing member 70 may include particles of alumina (Al₂O₃), zirconia (ZrO₂), glass (SiO₂), and the like. A ceramic particle, including a titanium oxide particle, functions as an aggregate when mixed with the SQ-based resin. Thus, the hardness of the first sealing member 70 be increased, and the coefficient of thermal expansion thereof can be decreased. Consequently, such a particle is suitable as a joint member (sealing member) bonding and sealing both the lead electrodes 10, 20 and the frame 40.

As shown in FIGS. 1A and 1D, the second sealing member 80 is provided so as to cover the side and upper surfaces of the light emitting device 50, the upper surfaces of the lead electrodes 10, 20, and the upper surface of the first sealing member 70 and to fill the recess of the housing 100. Moreover, the second sealing member 80 is made of resin obtained by mixing medium resin allowing light emitted from the light emitting device 50 to penetrate therethrough with a phosphor that absorbs light emitted from the light emitting device 50 and emits phosphorescent light. The second sealing member 80 directly contacts the surfaces of the light emitting device 50 and the surfaces of the lead electrodes 10, 20 around the light emitting device 50, but in other regions, contacts the first sealing member 70 and the frame 40 made of the resins. Any of the second sealing member 80, the first sealing member 70, and the frame 40 is made of the resin, and therefore, is high in adhesion. This can prevent a decrease in light output due to separation of the second sealing member 80 from the light emitting device 50 or the housing 100.

The second sealing member 80 is made of resin obtained by mixing dimethyl silicone resin as medium resin with LSN:Ce phosphor particles, which are obtained by adding a cerium (Ce) activator agent to lanthanum silicon nitride (LSN) having a particle size of 10 μm to 50 μm, as a phosphor. The coefficient of thermal expansion of the dimethyl silicone-based resin used in the embodiment is 212 ppm° C.⁻¹, and the hardness (durometer type A (shore A) according to JIS K 6253) thereof is A65 to A78. Note that examples of the medium resin to be used may include dialkyl silicone-based resins, epoxy-based resins, acrylic-based resins, polycarbonate-based resins, and the like.

As the phosphor contained in the second sealing member 80, for example, one or more phosphors selected from a YAG:Ce phosphor, which is obtained by adding a cerium (Ce) activator agent to yttrium aluminum garnet (YAG), as a yellow phosphor, a β sialon phosphor as a green phosphor, and a silicon nitride-based phosphor (CASN, SCASN) and a silicon fluoride-based phosphor (KFS) as red phosphors may be used.

As described above, the semiconductor light emitting apparatus 1 has such a structure that the first sealing member 70 is provided at the recess-side end portions of the contact surfaces 40c between the lead electrodes 10, 20 and the frame 40, so that adhesion between the lead electrodes 10, 20 and the frame 40 can be improved.

### (Manufacturing Method)

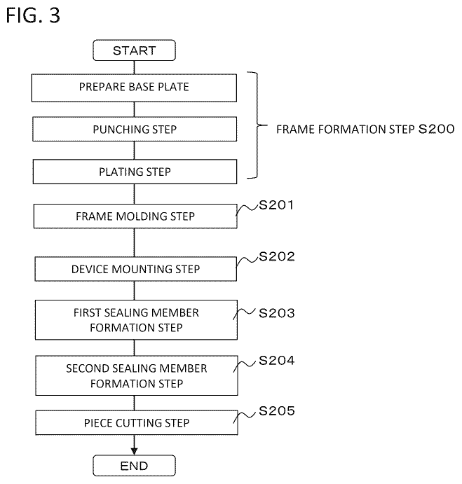

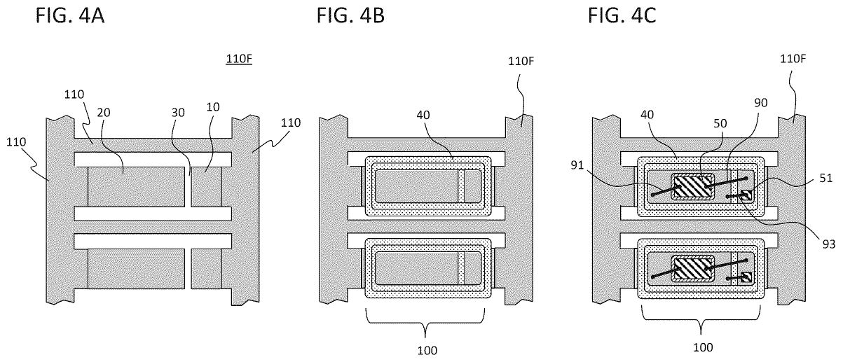

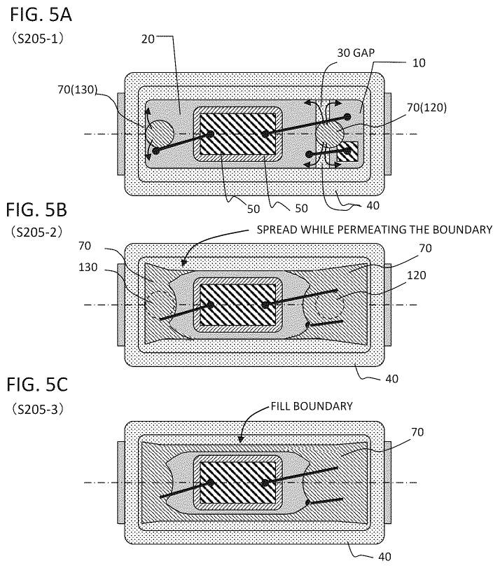

Next, a method for manufacturing the semiconductor light emitting apparatus 1 of the embodiment will be described. FIG. 3 shows the flow of steps of manufacturing the semiconductor light emitting apparatus 1. Moreover, FIGS. 4A to 4C and FIGS. 6A to 6C show schematic views showing a process of manufacturing the semiconductor light emitting apparatus 1. FIGS. 5A to 5C are views showing a process of forming a first sealing member in a first sealing member formation step. Note that the manufacturing method will be described assuming that a plurality of semiconductor light emitting apparatuses 1 is coupled in a grid pattern.

First, a frame formation step of forming a frame 110F by providing an electrode coating on a frame base material formed by removing portions other than lead electrodes 10, 20 and lead electrode support portions 110 supporting the lead electrodes 10, 20 from a metal plate is performed (S200). Specifically, a Cu plate having such a size (vertical length×horizontal length×thickness: 60 mm×140 mm×0.2 mm) that a plurality of semiconductor light emitting apparatuses 1 can be simultaneously formed is subjected to punching, and thereby a lead base material from which the portions other than the lead electrodes 10, 20 and the lead electrode support portions 110 have been removed is formed. Subsequently, by electroplating, the frame 110F with a plating layer (Ni/Au layer) formed by stacking Ni (0.5 μm) and Au (2.5 μm) in this order on the surface of the lead base material is formed (FIG. 4A). Note that for the plating layer, silver (Ag) with high reflectivity of light in a visual light wavelength band may be used.

Next, a frame molding step of molding the frames 40 filling the gaps 30 of the frame 110F, standing at the peripheral edges of the lead electrodes 10, 20, and covering the side surfaces of the lead electrodes 10, 20 is performed (S201). In this manner, the housings 100 are formed. Specifically, the frame 110F is sandwiched by divided upper and lower molds having recesses corresponding to the frames 40, and a precursor (thermosetting dimethyl silicone resin containing titanium oxide particles) to be the frames 40 is press-fitted in the recesses of the molds. The molds are heated at 150° C. for 120 minutes, and a composite molded article of the frame 110F and the frames 40 obtained by integral molding is molded as the housings 100 (FIG. 4B).

Next, a device mounting step of mounting the protective devices 51 on the first lead electrodes 10 and mounting the light emitting devices 50 on the second lead electrodes 20 in the recesses of the housings 100 is performed (S202). Specifically, conductive paste is applied to the upper surfaces of the first lead electrodes 10, and the protective devices 51 are placed thereon. Moreover, the adhesive members 60 are applied to the upper surfaces of the second lead electrodes 20, and the light emitting devices 50 are placed thereon. Thereafter, the resultant is heated at 150° C. to 180° C. for 30 minutes to 60 minutes to cure the conductive paste and the adhesive members 60, and in this manner, the protective devices 51 and the light emitting devices 50 are bonded (die-bonded) to the first lead electrodes 10 and the second lead electrodes 20. Upper electrodes of the protective devices 51 and the second lead electrodes 20 are connected to each other via the Au bonding wires 93. Similarly, one upper electrode of each light emitting device 50 is connected to the first lead electrode 10 via the Au bonding wire 90. The other upper electrode of each light emitting device 50 is connected to the second lead electrode 20 via the Au bonding wire 91. In the above-described manner, the light emitting devices 50 and the protective devices 51 are mounted on the bottom surfaces of the housings 100 (FIG. 4C).

Next, a first sealing member formation step of forming the first sealing members 70 to cover the recess outer edge boundary 41 and the recess gap boundary 42 of each housing 100 on which the light emitting device 50 and the protective device 51 are mounted is performed (S203). Specifically, as shown in FIG. 5A, a precursor (SQ-based resin containing TiO₂ particles) to be the first sealing member 70 is applied to a first position 120 on the frame 40 filling the gap 30 between the first lead electrode 10 and the second lead electrode 20. Moreover, the precursor to be the first sealing member 70 is applied to a second position 130 contacting a boundary between the upper surface of the second lead electrode 20 and the inner wall surface 40d of the frame 40 on the short side. The resultant is left stand for a while, and accordingly, each precursor spreads by capillary action along the inner wall surface 40d of the frame 40 on the short side as shown in FIG. 5B. Subsequently, as shown in FIG. 5C, each precursor spreads along the boundary between the second lead electrode 20 and the long side of the frame body 40, and then the precursors are bonded to each other. After bonding precursors of the first sealing member 70, the precursor is heated at 150° C. for 3 minutes to 10 minutes, and is temporarily cured. In this manner, the first sealing member 70 is formed (FIG. 6A).

The first sealing member 70 spreads across the recess of the housing 100 as described above, and therefore, connection portions between the light emitting device 50 and the lead electrodes 10, 20 via the bonding wires 90, 91 are embedded therein. Moreover, the first sealing member 70 is formed so as to expose a part of the upper surface of the second lead electrode in the short side direction of the frame 40 of the light emitting element 50.

Next, a second sealing member formation step of forming the second sealing members 80 to cover the upper and side surfaces of the light emitting devices 50, the second lead electrodes 20 exposed on the first sealing members 70, and the first sealing members 70 is performed (S204). Specifically, a precursor (dimethyl silicone resin containing TiO₂ particles) to be the second sealing members 80 is injected until filling the openings of the recesses of the housings 100 beyond the upper surfaces of the light emitting devices 50. The resultant is left stand for a while, and thereafter, is heated at 150° C. for three hours. In this manner, the precursor resin is fully cured to form the first sealing members 70 and the second sealing members 80 (FIG. 6B).

Finally, a piece cutting step of cutting a single semiconductor light emitting apparatus 1 from the frame 110F is performed (S205). Specifically, the lead electrodes 10, 20 and the lead electrode support portion 110 protruding from the housing 100 are cut by tiebar cutting, and in this manner, the single semiconductor light emitting apparatus 1 is formed (FIG. 6C).

In the above-described manufacturing method, the first sealing member formation step (S203) is performed after the device mounting step (S202), and therefore, even if separation of the contact surfaces 40b, 40c between the lead electrodes 10, 20 and the frame 40 is caused in the device mounting step (S202), the first sealing member 70 can permeate the separated portion to close such a separated portion.

The first sealing member 70 is temporarily cured in the first sealing member formation step (S203), and the first sealing member 70 and the second sealing member 80 are fully cured in the second sealing member formation step (S204). Thus, the semiconductor light emitting apparatus 1 can be formed without stress on the first sealing member 70.

As described above, the structure in which the first sealing member 70 is provided so as to cover both the boundaries (recess outer edge boundary 41, recess gap boundary 42) can prevent separation due to the residual stress and the external stress between the lead electrodes 10, 20 and the frame 40 as the composite molded article in the housing 100. Moreover, even if separation is caused at the boundary between the lead electrodes 10, 20 and the frame 40, the first sealing member 70 contacting (joining) both the lead electrodes 10, 20 and the frame 40 in the circular ring shape can maintain the sealed state. Thus, even in a case where there is corrosive gas such as nitrogen oxide or sulfur oxide outside the semiconductor light emitting apparatus 1, entrance of such gas into the semiconductor light emitting apparatus 1 can be prevented.

As described above, according to the present invention, the semiconductor light emitting apparatus and the method for manufacturing the semiconductor light emitting apparatus can be provided, which result in high adhesion between the lead frame and the sealing resin and high reliability.

The first sealing member 70 with high hardness covers the connection portions between the bonding wires 90, 91, 93 and the lead electrodes 10, 20, and therefore, corrosion and separation (disconnection) of the bonding wires 90, 91, 93 at these connection portions can be prevented. Thus, the highly-reliable semiconductor light emitting apparatus can be provided.

The first sealing member 70 covers the upper surfaces (front surfaces) of the lead electrodes 10, 20, and therefore, the decrease in light output due to separation of the second sealing member 80 can be suppressed. Thus, the highly-reliable semiconductor light emitting apparatus can be provided.

The above-described embodiment is merely one exemplary embodiment. For example, the recess of the housing 100 may be in a square shape or a circular shape. Moreover, the gap 30 between the lead electrodes 10, 20 may be in a corrugated shape or a crank shape. Further, the light emitting device 50 may include a plurality of light emitting devices 50 provided in series or in parallel. In this case, three or more lead electrodes are provided. In addition, the light emitting device 50 may be mounted by flip chip bonding for which no bonding wire is necessary.

What is claimed is:

1. A semiconductor light emitting apparatus comprising:
a housing;
a light emitting device;
a first sealing member; and
a second sealing member, wherein
the housing includes a first lead electrode and a second lead electrode disposed on an identical plane with a gap therebetween, and a resin frame disposed on the first lead electrode and the second lead electrode and at peripheral edges thereof, the frame forms a recess surrounded by the frame, and upper surfaces of the first lead electrode and the second lead electrode form a bottom surface of the recess,
the light emitting device is bonded onto the second lead electrode via an adhesive member in the recess,
the first sealing member contacts the bottom surface of the recess around the light emitting device and an inner wall surface of the frame,
the second sealing member covers the light emitting device and the first sealing member, and fills the recess,
resin forming the frame extends into the gap between the first lead electrode and the second lead electrode to fill the gap, and an upper surface of the resin filling the gap forms part of the bottom surface of the recess, and
the upper surface of the resin filling the gap is covered with the first sealing member.

2. The semiconductor light emitting apparatus according to claim 1, wherein
a hardness of the first sealing member is less than hardnesses of the first lead electrode and the second lead electrode and greater than a hardness of the frame.

3. The semiconductor light emitting apparatus according to claim 1, wherein
a hardness of the first sealing member is greater than a hardness of the second sealing member.

4. The semiconductor light emitting apparatus according to claim 1, wherein
the first sealing member contains silsesquioxane-based (SQ-based) resin expressed by a composition formula [(RSiO_{1.5})n] (R: alkyl group, n: integer).

5. The semiconductor light emitting apparatus according to claim 4, wherein
a medium resin of the first sealing member and a medium resin of the adhesive member are resin of an identical type.

6. The semiconductor light emitting apparatus according to claim 1, wherein
the bottom surface of the recess is in a rectangular shape in top view, and on the bottom surface of the recess between the frame located on a short side of the bottom surface and an outer peripheral side of the light emitting device facing the frame on the short side, a region closer to the frame is covered with the first sealing member and a region closer to the light emitting device is not covered with the first sealing member.

7. The semiconductor light emitting apparatus according to claim 6, wherein
a pair of device electrodes is disposed on an upper surface of the light emitting device, one of the pair of device electrodes is connected to the first lead electrode via a first wire, the other device electrode is connected to the second lead electrode via a second wire, and a connection portion between the first wire and the first lead electrode and a connection portion between the second wire and the second lead electrode are embedded in the first sealing member.

8. A method for manufacturing a semiconductor light emitting apparatus, comprising:
a step of forming, from rein containing a light-reflecting particle, a frame along edges of upper surfaces of a first lead electrode and a second lead electrode disposed on an identical plane with a gap therebetween;
a step of bonding, with an adhesive member, a light emitting device to the upper surface of the second lead electrode surrounded by the frame;
a step of wire-bonding a pair of upper electrodes on an upper surface of the light emitting device to the upper surfaces of the first lead electrode and the second lead electrode;
a step of applying a resin containing light-reflecting particle to the upper surfaces of the first lead electrode between the frame and the light emitting device and the second lead electrode between the frame and the light emitting device, and spreading the resin by capillary action to a corner at where the inner wall surface of the frame and the upper surfaces of the first lead electrode contact and a corner where the inner wall surface of the frame and the upper surfaces of the second lead electrode contact, thereby forming a first sealing member contacting the first lead electrode and the second lead electrode inside a recess surrounded by the frame and an inner wall surface of the frame; and
a step of forming a second sealing member covering an upper surface of the first sealing member, the upper surfaces of the first lead electrode and the second lead electrode, and side and upper surfaces of the light emitting device by filling the inside of the frame with resin containing a phosphor, wherein
in the step of applying a resin containing a light-reflecting particle, the resin is applied to preset positions between the frame and the light emitting device such that the resin spread by capillary action to the corner does not contact the light emitting device.

9. The method for manufacturing the semiconductor light emitting apparatus according to claim 8, wherein
a hardness of the first sealing member after curing is greater than a hardness of the frame after curing.
